(19) United States
(12) Patent Application Publication
(10) Pub. No.: US 2019/0319425 A1
(43) Pub. Date: Oct. 17, 2019

(54) Flat plane laser light

(71) Applicant: William Delaplaine Green, JR., Alexandria, VA (US)

(72) Inventor: William Delaplaine Green, JR., Alexandria, VA (US)

(21) Appl. No.: 15/932,713

(22) Filed: Apr. 14, 2018

(51) Int. Cl. H01S 5/068; H01S 5/042

(52) U.S. Cl. CPC H01S 5/06808; H01S 5/0427

(57) ABSTRACT

The invention is a Flat Plane Laser Light including a coherent light source means, a flat plane laser light circuit means, a power supply circuit means, a battery circuit means, a laser means, and a mirror means to reflect the laser light into an ever increasing circumference and electricity output connection means to supply electrical circuits with the necessary electricity required by the design specifications of the connected electric apparatus.

### INTRODUCTION

This is a United States Utility Patent Application based on a United States Provisional Patent Application mailed to the Commissioner for Patents, P.O. Box 1450, Alexandria, Va. 22313-1450 in the Express Mail on Apr. 10, 2017, tracking number EL804310129 US.

### BACKGROUND OF THE INVENTION

Before this invention usable electricity was generally made by a central power plant that distributed the generated electricity to the local region and the electric power grid. These power plants had to produce energy of their own through the use of fire, heat, water movement, wind, nuclear fission etc. to drive what is well known in the art as a turbine generator set that could alternately be a turbine alternator set to generate either alternating current or direct current depending upon the application of the electricity generated. Usable electricity can also be generated by a home power plant and idea filed on with the USPTO by the inventor. The electricity generated could be stored in a battery, a capacitor or other means or it had to be generated on demand and used up. Most of the electricity is fed through power lines and transformer stations to the consumer requiring an enormous infrastructure of installed power lines and distribution system to send electricity to the customer. At the customer's location the electricity is usually fed through an internal electrical system of the building receiving the electric supply. To support their use of the electricity the consumer usually set up an account with the local power company and receives a bill each month for the electricity consumed at that particular location. Electricity use in the US is a big business involving enormous amounts of fossil fuel, nuclear waste, power consumption, oil, gas, coal, dams, power lines and poles, distribution lands, transformer stations to step and down voltage of the AC electricity supply and lines and outlets in each building using the electricity available.

This system generates electricity charged to the customer by the kilowatt hour of electricity consumed and that cost is truly enormous generating trillions of dollars of income for American electric power companies, fossil fuel companies, atomic power companies, wind turbine companies, dam building and reservoir construction companies, power line companies, and construction builders paying electricians to design and install the required electric wiring, fuse panels, electric outlets, lights, appliances and heating elements used in American buildings, automobiles, appliances, power tools and equipment using electricity such as saws, drills, battery chargers, batteries, electric lawn mowers and chain saws, heating and AC unites, stoves, ovens, ranges, microwave ovens, blenders, mixers, can openers, toasters, coffee makers, clothing washers and dryers, food refrigerators and freezers, dish washers, stereo systems including amplifiers, loudspeakers, radios FM and AM, lighting, including automated factories that use electrically driven machinery to manufacture everything from and tin cans to spaceships and everything in between including trains, planes, ships, automobiles, trucks, submarines, farm equipment, lathes, milling machines, bulldozers, loaders, excavators, mining tools, roads, highways and practically everything else under the sun made and used by modern civilization, mankind and the nations of the world we live in. Electricity is one of the most valuable and useful products made by man.

By comparison the invention can make all electrical machines and devices electrically independent of a common power source commonly referred to in the art as an electric power plant.

### BRIEF DESCRIPTION OF THE DRAWING FIGURES

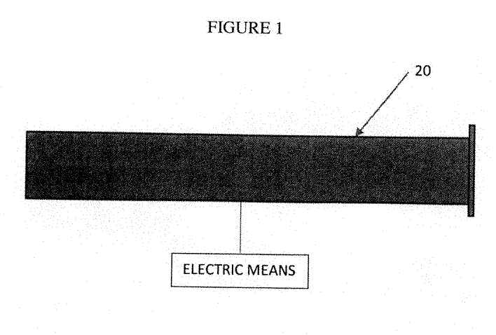

1. FIG. 1 is a top view of a Flat Plane Laser Light illustrated is drawing FIG. 1 and enumerated therein by numeral 20 and described and illustrated in the Patent Application Specification, Claims, Abstract and Drawings of this United States Utility Patent Application.

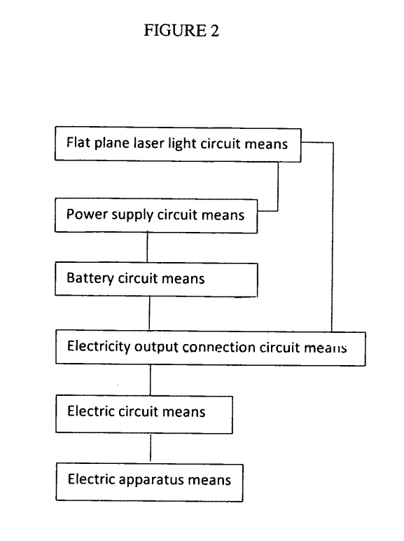

2. FIG. 2 is an electric circuit for the Flat Plane Laser Light illustrated in drawing FIG. 1 and enumerated therein by numeral 20 and described and illustrated in the Patent Application Specification, Claims, Abstract and Drawings of this United States Utility Patent Application.

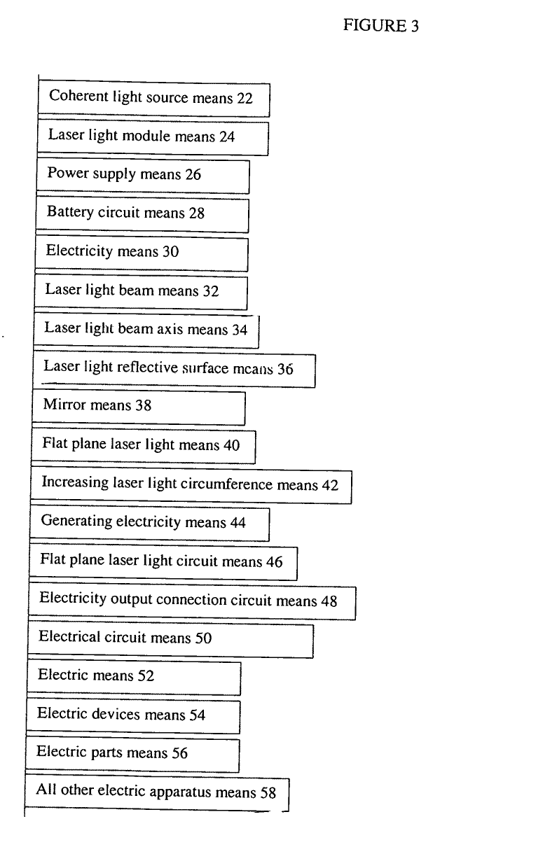

3. FIG. 3 is a list of Common Means for the Flat Plane Laser Light illustrated in drawing FIG. 1 and enumerated therein by numeral 20 and described and illustrated in the Patent Application Specification, Claims, Abstract and Drawings of this United States Utility Patent Application.

### DETAILED DESCRIPTION OF THE PREFERRED EMBODIMENT

The invention is a Flat Plane Laser Light enumerated in drawing FIG. 1 by numeral 20. The invention includes a coherent light source means 22 that may include a laser light module means 24 that may be powered by a power supply means 26 that may include a battery circuit means 28 to supply electricity means 30 to said power supply means for powering said laser light module means with electricity for sending a laser light beam means 32 along an axis 34 to a laser light reflective surface means 36 that may include a mirror means 38 for reflecting said laser light beam means along a straight path to spread the laser light beam means into a flat plane laser light means 40 that radiates coherent light outwards in an ever increasing laser light circumference means 42 for generating electricity means 44 within a flat plane laser light circuit means 46 and electricity output connection means 48 for connection to electric circuits means 50 and for sending electricity to electric means 52, including but not limited to electric motors, alternator and generators, electric devices means 54, including but not limited to circuit boards, computer modules, heating elements, solenoids, stereos, fans, lights, transmitters, receivers, battcries, transformers, computers, radios, radar, television, electric parts means 56 such as switches, wires, outlets, plugs, connectors, transistors, integrated circuits, CPU, OP amps, and all other electric apparatus means 58 including but not limited to a resistor, a capacitor, a coil, a diode.

### OPERATION OF THE INVENTION

Electrically connect to the Flat Plane Laser Light electricity connection circuit means to use the electricity generated by the flat plane laser light circuit means.

What I claim is:

1. In a flat plane laser light for the production of a electricity that includes a coherent light source means 22 that includes a laser light module means 24 powered by a power supply means 26 including a battery circuit means 28 to supply electricity means 30 to said power supply means for powering said laser light module means with electricity for sending a laser light beam means 32 along an axis 34 to a laser light reflective surface means 36 that includes a mirror means 38 for reflecting said laser light beam means along a straight path to spread the laser light beam means into a flat plane laser light means 40 that radiates coherent light outwards in an ever increasing laser light circumference means 42 for generating electricity means 44 within a flat plane laser light power circuit means 46 and electricity output connection means 48 for connection to electric circuits means 50 for sending electricity to electric means 52.

2. A flat plane laser light for the production of electricity comprised of a power source circuit means including of a battery circuit means for supplying electricity to a connected coherent light source means for making a laser light that shines on a connected mirror means wherein the improvement comprises an electric outlet circuit means connected to said power source circuit means to supply electricity to connected electric machines and apparatus.
